(19) United States
(12) Patent Application Publication
(10) Pub. No.: US 2017/0235348 A1
(43) Pub. Date: Aug. 17, 2017

(54) HEAT VENTING MECHANISM

(71) Applicant: AirWire Technologies, Reno, NV (US)

(72) Inventor: Forrest Wolf, Reno, NV (US)

(21) Appl. No.: 15/045,002

(22) Filed: Feb. 16, 2016

(51) Int. Cl. G06F 1/20; H05K 7/20

(52) U.S. Cl. CPC G06F 1/20; H05K 7/20127; H05K 7/20136

(57) ABSTRACT

Provided herein is an apparatus including circuitry as well as membrane that is configured to pass air, to remove heat from the circuitry, and to prevent the circuitry from being exposed to moisture. The membrane is additionally includes pores.

### BACKGROUND

Electronic devices, such as computers, laptops, cellular phones, iPads, etc., have seen a tremendous surge in data processing speeds and functionality in the recent years. This increase in data processing speed and corresponding increase in functionality combined with a trend of smaller electronic devices has led to extremely compact devices that generate excessive heat. Moreover, by placing electronic devices in protective cases that are airtight or close to airtight, heat generated from within the electronic device (by way of the device's electronic components and circuitry) is unable to escape and further increases the device temperature. Increased temperatures of electronic devices not only create discomfort for a device user, but may also cause damage to the performance of electronic devices. Accordingly, heat management becomes more critical as technology advances and newer devices continue to become smaller and more compact.

### SUMMARY

Thus, a need has arisen to cool electronic devices to prevent the device from overheating. Accordingly, the present invention discloses a protective enclosure containing electronic components and circuitry that allows for the efficient dissipation of heat.

Provided herein is an apparatus including circuitry as well as a membrane that is configured to pass air, to remove heat from the circuitry, and to prevent the circuitry from being exposed to moisture. The membrane additionally includes pores.

Further provided herein is an apparatus that includes electronics that are configured to wirelessly connect to an internet service provider. The apparatus also includes an enclosure surrounding the electronic components and circuitry with both a first and a second portion. The first portion is more rigid than the second portion and the second portion keeps moisture away from the electronics and further allows for passage of gasses.

Also provided herein is an apparatus that includes an interior environment as well as circuitry configured to wirelessly provide internet service to a mobile device. The circuitry is located within the interior environment. The apparatus additionally includes a hydrophobic and air permeable layer that forms a boundary between the interior environment and an external environment.

These and other features and aspects of the concepts described herein may be better understood with reference to the following drawings, description, and appended claims.

### BRIEF DESCRIPTION OF DRAWINGS

The present invention is illustrated by way of example, and not by way of limitation, in the figures of the accompanying drawings and in which like reference numerals refer to similar elements.

FIG. 1 is a front-side view of the inner layer of a protective enclosure for an electronic device wherein a singular rectangular patch of protective membranous material is placed in the middle of the protective enclosure, according to an embodiment of the present invention.

FIG. 2 is a front-side view of the inner layer of a protective enclosure for an electronic device wherein strips of protective membranous material are placed horizontally across the top and bottom ends of the inner layer of the protective enclosure, according to an embodiment of the present invention.

FIG. 3 is a front-side view of the inner layer of a protective enclosure for an electronic device wherein multiple rectangular patches of protective membranous material are placed in various regions of the inner layer of the protective enclosure, according to an embodiment of the present invention.

FIG. 4 is a front-side view of the inner layer of a protective enclosure for an electronic device wherein strips of protective membranous material are placed vertically in various regions of the inner layer of the protective enclosure, according to an embodiment of the present invention.

FIG. 5 is a front-side view of the inner layer of a protective enclosure for an electronic device wherein strips of protective membranous material are placed horizontally across the top and bottom ends of the inner layer of the protective enclosure and a single fan is built into the inner layer of the protective enclosure, according to an embodiment of the present invention.

FIG. 6 is a front-side view of the inner layer of a protective enclosure for an electronic device wherein strips of protective membranous material are placed horizontally across the top and bottom ends of the inner layer of the protective enclosure and multiple fans are built into the inner layer of the protective enclosure, according to an embodiment of the present invention.

FIG. 7 is a side view of a portion of an electronic device where protective membranous material is integrated into the electronic device and is placed above the electronic device's circuitry, according to an embodiment of the present invention.

FIG. 8 is a side view of a portion of an electronic device where protective membranous material is integrated into the top and bottom surfaces of an electronic device and is placed both above and below the electronic device's circuitry, according to an embodiment of the present invention.

FIG. 9 is a side view of a portion of an electronic device where protective membranous material is integrated into the electronic device such that it completely surrounds the electronic device's circuitry, according to an embodiment of the present invention.

### DETAILED DESCRIPTION

Before various embodiments are described in greater detail, it should be understood by persons having ordinary skill in the art that the embodiments are not limiting, as elements in such embodiments may vary. It should likewise be understood that a particular embodiment described and/or illustrated herein has elements which may be readily separated from the particular embodiment and optionally combined with any of several other embodiments or substituted for elements of any of several other embodiments described here.

It should also be understood by persons having ordinary skill in the art that the terminology used herein is for the purpose of describing the certain concepts, and the terminology is not intended to be limiting. Unless indicated otherwise, ordinal numbers (e.g., first, second, third, etc.) are used to distinguish or identify different elements or steps in a group of elements or steps, and do not supply a serial or numerical limitation on the elements or steps of the embodiments thereof. For example, “first,” “second,” and “third” elements or steps need not necessarily appear in that order, and the embodiments thereof need not necessarily be limited to three elements or steps. It should also be understood that, unless indicated otherwise, any labels such as “left,” “right,” “front,” “back,” “top,” “middle,” “bottom,” “forward,” “reverse,” “clockwise,” “counter clockwise,” “up,” “down,” “side,” or other similar terms such as “upper,” “lower,” “above,” “below,” “vertical,” “horizontal,” “proximal,” “distal,” and the like are used for convenience and are not intended to imply, for example, any particular fixed location, orientation, or direction. Instead, such labels are used to reflect, for example, relative location, orientation, or directions. It should also be understood that the singular forms of “a,” “an,” and “the” include plural references unless the context clearly dictates otherwise.

Unless defined otherwise, all technical and scientific terms used herein have the same meaning as commonly understood by persons of ordinary skill in the art to which the embodiments pertain.

The present invention discloses a protective enclosure for electronic components and circuitry devices that incorporates a waterproof and breathable protective membrane, which serves as a barrier to prevent damage to an electronic device from a multitude of elements, including, but not limited to, dirt, dust, particulates, water, and excessive heat.

In a non-limiting example, the present invention can be used for a device in a taxicab deploying a 4G LTE WiFi service, wherein the compactness and multi-functionality of the device causes it to run extremely hot. The present invention permits the device to be “vented.” Specifically, the air permeability of the present invention's protective membrane allows the device to first intake air and second circulate the air in, up, and then out, thereby drawing heat away from the heat-generating components and circuitry of electronic device and replacing it with cool air using principles of natural convection.

Other non-limiting examples include the present invention preventing water damage to an electronic device resulting from a user's device being exposed to humidity, rain, bodies of water, or spilled beverages; preventing damage to an electronic device from dirt, sand, grit, or other external elements that may fall into the openings or cracks of an electronic device; preventing a compact mobile electronic device from overheating when a multitude of its functionalities are engaged (e.g. GPS, video, internet); etc.

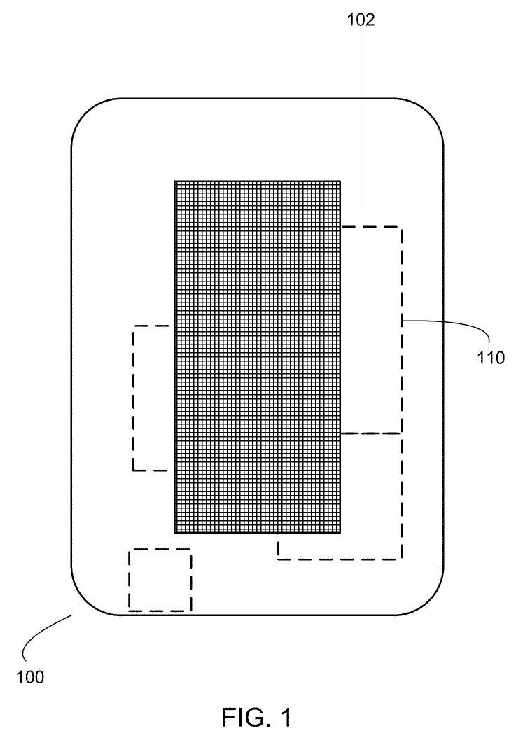

Referring now to FIG. 1, a front-view of the inner layer of protective enclosure 100 for an electronic device is shown. The inner layer of protective enclosure 100 includes a protective membrane 102. The electronic components and circuitry 110 of the electronic device contained within protective enclosure 100 are schematically illustrated or are omitted. The outer layer of protective enclosure 100 is also omitted.

The electronic device within protective enclosure 100 can define computers, laptops, cellular phones, iPads, or any other electronic computing device. For brevity, such devices are identified generically as electronic devices.

In one embodiment, protective membrane 102 is a flexible material including a thickness and shape required to generate the type of protection desired for the invention. Protective membrane 102 is further characterized by hydrophobic and breathable microporous material that serves as a barrier to prevent damage to an electronic device.

Various embodiments may use protective membrane 102 to protect an electronic device from a multitude elements, including, but not limited to, dirt, dust, particulates, water, extreme humidity, sweat, and excessive heat.

For example, electronic devices, particularly mobile electronic devices, are often used outdoors and are susceptible to harmful environmental elements, including dirt, dust, sand, and the like. Thus, as understood, in one embodiment of the present invention, protective membrane 102 serves as a barrier to the aforementioned materials and similar unnamed materials from entering an electronic device and interfering with its functionality.

Protective membrane 102 is also characterized by hydrophobic properties. Specifically in various embodiments, protective membrane 102 is characterized by micropores that are small enough to prevent passage of liquid water molecules. For example, in some embodiments the micropores may be at least 20,000 times smaller than a water droplet, such that water cannot penetrate the protective membrane and damage the electronic device.

Accordingly, in embodiments of the present invention, the protective membrane 102 protects electronic devices threatened by water damage (e.g. electronic devices subject to rain or bodies of water, electronic devices placed on surfaces along with drinks such as soda or coffee, which, upon spilling, easily slip through openings or cracks in an electronic device, etc.).

Protective membrane 102 contains additional heat venting or heat dissipation properties. In particular in various embodiments, protective membrane 102 is includes micropores that are large enough to allow passage of water vapor molecules. For example, in some embodiments the micropores may be at least 700 times larger than a water vapor molecule such that the protective membrane 102 facilitates the movement of air through an electronic device such that the air removes heat from the electronic circuitry 110. In some embodiments, the air permeability of protective membrane 102 allows one cubic foot of air or less to pass through one cubic foot of fabric in one minute. In various embodiments, the air permeability of protective membrane 102 allows one cubit foot of air or more to pass through one cubic foot of fabric in one minute.

Therefore, in embodiments of the present invention, protective membrane 102 protects electronic devices from excessive heat generated from external factors, including high temperatures and hot climates, and from heat generated from within the electronic device, including from electronic circuitry 110. External and internal excessive heat may rise to the surface of an electronic device and cause discomfort to the user. Excessive heat may additionally cause damage to the electronic device itself. As explained above, the air permeability of protective membrane 102 permits perspiration to pass through an electronic device and remove potential damage-causing heat.

The current embodiment of the present invention displays protective membrane 102 as a single rectangular patch, but the protective membrane may exist in a multitude of configurations, including multiple rectangular patches, circular patches, irregular shaped patches, custom fit patches for a particular electronic device, etc.

Electronic circuitry 110 is located in the interior environment of protective enclosure 100 and permits the electronic device contained within protective enclosure 100 to implement a number of functions.

In a non-limiting example, electronic circuitry 110 is configured to receive cellular signals from an internet service provider and communicate with the mobile device using a WiFi signal. In other embodiments, electronic circuitry 110 permits a user to run various applications (e.g. music, videos, games), to send and receive GPS information, to establish Bluetooth connections, to establish USB connections, etc.

Protective membrane 102 forms a boundary between the interior environment where electronic circuitry 102 is located, and the exterior environment, protecting electronic circuitry 110 from potentially harmful exposure to dirt, dust, water, excessive heat, and the like.

This embodiment of the present invention is representative of a multi-layer protective enclosure, wherein the innermost layer incorporates protective membrane 102 and the outer layer(s) (not pictured) may be made from various materials, including plastic, metal, rubber, or any other type of material that can generate the type of protection desired for the present invention.

The outer layer(s) of the present embodiment may further incorporate perforations or vent holes to promote heat dissipation away from the electronic components and circuitry 110.

Additional embodiments of the present invention include, but are not limited to, a protective enclosure including a single layer incorporating protective membrane described 102 above or a protective membrane 102 integrated into the electronic device itself.

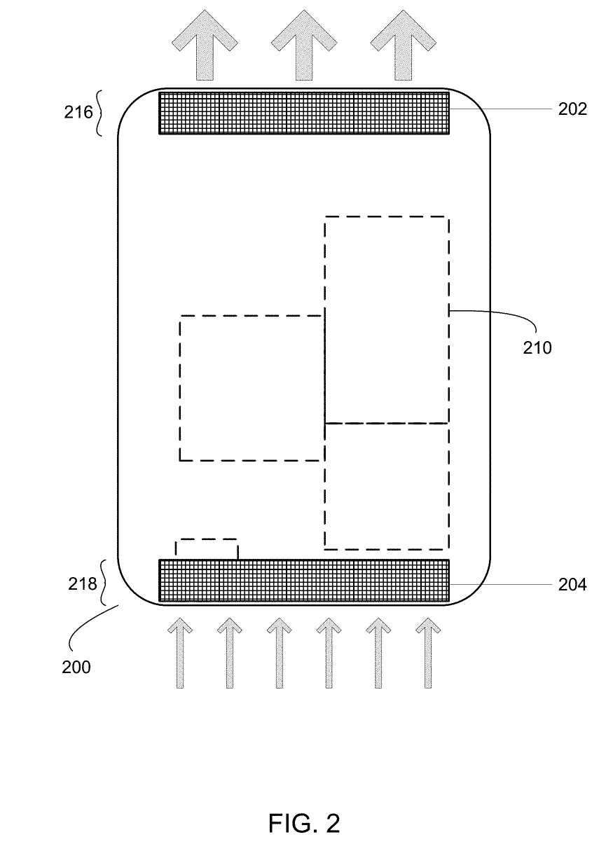

Referring to FIG. 2, a front-side view of the inner layer of protective enclosure 200 displaying an alternative configuration for placement of the protective membrane is shown.

In this embodiment of the present invention, protective membranes 202 and 204 are shaped (e.g. cut, molded, woven, etc.) into rectangular strips and placed at top end 216 and bottom end 218 of the protective enclosure, such that they correspond to the top and bottom ends of the electronic device contained within protective enclosure 200.

Further embodiments may include numerous different configurations, of the position of membranes 202 and 204. For example, two rectangular strips of protective membranes may each be positioned on the top and bottom ends of the back-side of the protective enclosure 200 or may wrap around top end 216 and bottom end 218 such that each rectangular strip of protective membranes reach both the front and the back-side of protective enclosure 200.

In another embodiment, rectangular strips of protective membranes may be situated on the left and right sides of protective enclosure. For example, the rectangular strips of protective membranes may be positioned on the left and right side of the front-side of protective enclosure 200 or on the left and right side of the back-side of protective enclosure 200. Each rectangular strip of protective membranes may also wrap around the left and right sides of the protective enclosure such that each of the protective membranes reach both the front side and back side of protective enclosure 200.

The current embodiment of the present invention displays protective membranes 202 and 204 as rectangular strips, but the protective membrane may exist in a multitude of configurations, including multiple rectangular patches, circular patches, irregular shaped patches, custom fit patches for a particular electronic device, etc.

FIG. 2 displays the airflow through protective membranes 202 and 204. As illustrated, cooler air flows in through protective membrane 204 at bottom end 218 of the protective enclosure, absorbs heat from the electronic circuitry 210, and then hotter air flows out through protective membrane 202 at top end 216.

The above-described airflow may be accomplished via the principles of convection. With respect to heat generated by electronic devices, convection allows the air flowing into a protective enclosure containing an electronic device to absorb heat from those electronic parts. This air becomes lighter and thus naturally rises through the electronic device such that it exits through protective membrane 202 at top end 216. Cool air then flows in through protective membrane 204 at bottom end 218 to replace the hot air that has dissipated, thereby cooling the electronic device.

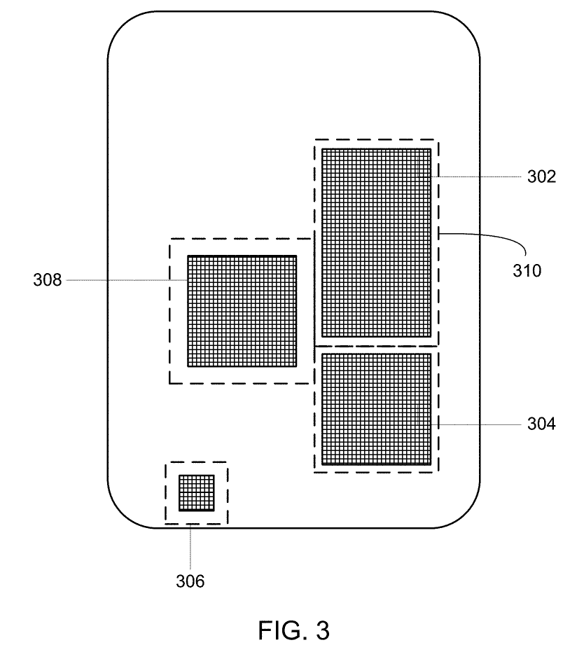

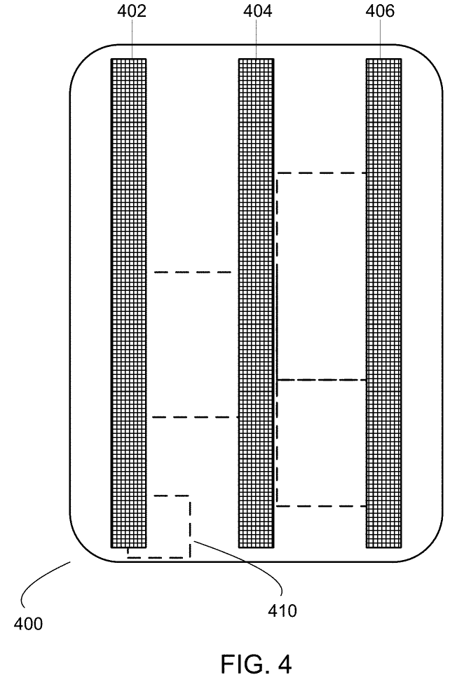

The embodiments of FIGS. 3 and 4 provide alternative configurations for the placement of protective membrane on the inner layer of a protective enclosure for an electronic device.

FIG. 3 discloses protective membranes 302, 304, and 306 as multiple rectangular membranous patches placed over electronic circuitry 310.

Electronic circuitry 310 permits of number of user functions including receiving cellular signals from an internet service provider and communicating with the mobile device using a WiFi signal, running various applications and programs (e.g. music, videos, games), sending and receiving GPS information, establishing Bluetooth connections, establishing USB connections, etc.

In this embodiment, protective membranes 302, 304, and 306 have been placed over the portions of the electronic device that generate the most heat. Specifically, they are placed over electronic circuitry 310. This prevents heat from spreading through the electronic device and heating up additional electronic components and circuitry.

Other embodiments may position protective membranes over various portions of the components of the electronic device that generate the most heat or, alternatively, may place protective membranes over components that do not generate the most heat. In these embodiments, principals of natural convection still permit cooler air to flow in through a protective membrane placed toward the bottom end of an electronic device, to then absorb heat from the electronic circuitry 310, and finally to flows out through a protective membrane placed toward the top end of an electronic device.

The current embodiment of the present invention displays protective membranes 302, 304 and 306 as rectangular patches, but the protective membrane may exist in alternative configurations, including (but not limited to) circular patches, irregular shaped patches, custom fit patches for a particular electronic device, etc.

FIG. 4 discloses protective membranes 402, 404, and 406 as multiple rectangular vertical strips placed equidistant from one another and placed over various regions of the electronic device's circuitry.

In this embodiment, protective membranes 402,404, and 406 are configured such that each is placed over at least a portion of the electronic device's circuitry 410. As such, the heat generated from the electronic device's circuitry 410 is prevented from spreading to other electronic components within the device, helping maintain a safe temperature level for a better user experience and for maintenance of device health.

In the present embodiment, the protective membranes 402, 404, and 406 extend the length of protective enclosure 400 and are oriented vertically. In this embodiment, cooler air can flow in through the bottom ends of protective membranes 402, 404, and 406 and absorb heat from the electronic circuitry 410. Hot air can then flow out through the top ends of protective membranes 402, 404, and 406, thereby keeping the device cool.

In another embodiment, protective membranes 402, 404, and 406 may extend the width of protective enclosure 400 and be oriented horizontally. In this embodiment, cooler air can flow through first, a bottom-most membrane, and second, a middle membrane, absorbing heat from the electronic circuitry 410, until ultimately flowing out through the top-most protective membrane.

The current embodiment of the present invention displays protective membranes 402, 404, and 406 as rectangular strips, but the protective membrane may exist in a multitude of configurations, including multiple rectangular patches, circular patches, irregular shaped patches, custom fit patches for a particular electronic device, etc.

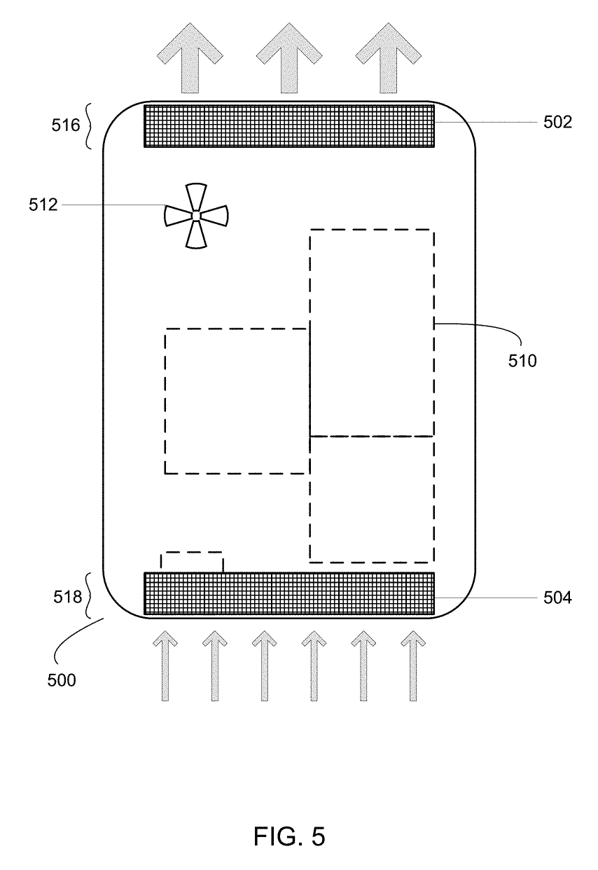

Referring now to FIG. 5, a front-view of the inner layer of protective enclosure 500 is shown wherein protective membranes 502 and 504 are shaped (e.g. cut, molded, woven, etc.) into rectangular strips and placed at top end 516 and bottom end 518 of the protective enclosure, such that they correspond to the top and bottom ends of the electronic device contained within protective enclosure 500. FIG. 5 additionally incorporates fan 512 in the inner layer of protective enclosure 500.

Protective membranes 502 and 504 are further characterized by hydrophobic and breathable microporous material that serves as a barrier to prevent damage to an electronic device. Various embodiments utilize protective membranes 502 and 504 for heat venting or heat dissipation.

Protective membranes 502 and 504 include micropores that may be at least 700 times larger than a water vapor molecule such that the protective membranes 502 and 504 permit perspiration to pass through and remove heat from the electronic circuitry 510 of an electronic device. In some embodiments, the air permeability of protective membranes 502 and 504 allow one cubic foot of air or less to pass through one cubic foot of fabric in one minute.

The current embodiment of the present invention displays protective membranes 502 and 504 as rectangular strips, but the protective membrane may exist alternative configurations, including multiple rectangular patches, circular patches, irregular shaped patches, custom fit patches for a particular electronic device, etc.

Fan 512 is installed to assist in natural convection already created by protective membranes 502 and 504. Fan 512 may be bi-directional. In a preferred embodiment, fan 512 will circulate air in the same direction as airflow the natural convection. The size and positioning of fan 512 within the inner layer of the protective enclosure may be modified based on the type and size of electronic device contained within protective enclosure 500.

FIG. 5 further illustrates the airflow through its protective membranes 502 and 504. Here, air flows in through protective membrane 504 at bottom end 518 of the protective enclosure, absorbs heat from the electronic circuitry 510, and then flows out through protective membrane 502 at top end 516. The airflow is achieved through principles of natural convention, which, in the current embodiment, is further assisted by fan 512.

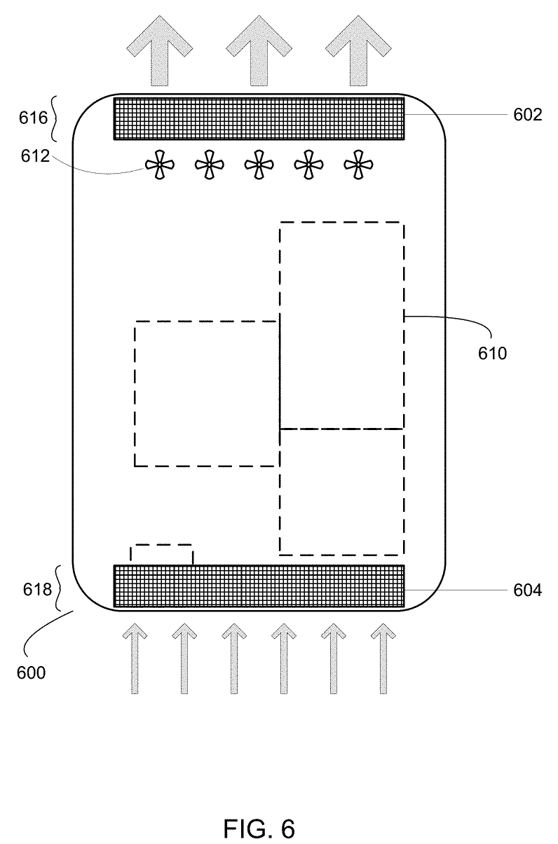

Referring now to FIG. 6, a front-side view of the inner layer of protective enclosure 600 is shown wherein protective membranes 602 and 604 are shaped (e.g. cut, molded, woven, etc.) into rectangular strips and placed at top end 616 and bottom end 618 of the protective enclosure, such that they correspond to the top and bottom ends of the electronic device contained within protective enclosure 600. FIG. 6 also contains fans 612.

The current embodiment of the present invention displays protective membranes 602 and 604 as rectangular strips, but the protective membrane may exist in a multitude of configurations, including multiple rectangular patches, circular patches, irregular shaped patches, and custom fit patches for a particular electronic device, etc.

Fans 612 include the installation of multiple fans to assist in natural convection already created by protective membranes 602 and 604. The fans 612 may be bi-directional. In a preferred embodiment, fans 612 will circulate air in the same direction as airflow the natural convection.

The size and positioning of fans 612 within the inner layer of the protective enclosure may be modified based on the type and size of electronic device contained within protective enclosure 600. The size of fans 612 also need not be uniform.

FIG. 6 further illustrates the airflow through its protective membranes. Here, air flows in through protective membrane 604 at bottom end 618 of the protective enclosure, absorbs heat from the electronic circuitry 610, and then flows out through protective membrane 602 at top end 616. The airflow is achieved through principles of natural convention and is assisted by fans 612.

Fans 612 of the present embodiment may be of particular use when an electronic device has been turned on its side or has been oriented such that the protective membranes 602 and 604 do not lend themselves to as efficiently promote principles of natural convection (i.e. air rising through an electronic device). In such situations, fans 612 help guide air in through one protective membrane and assist in the flow of hot air away from electronic circuitry 610 and out through the other protective membrane.

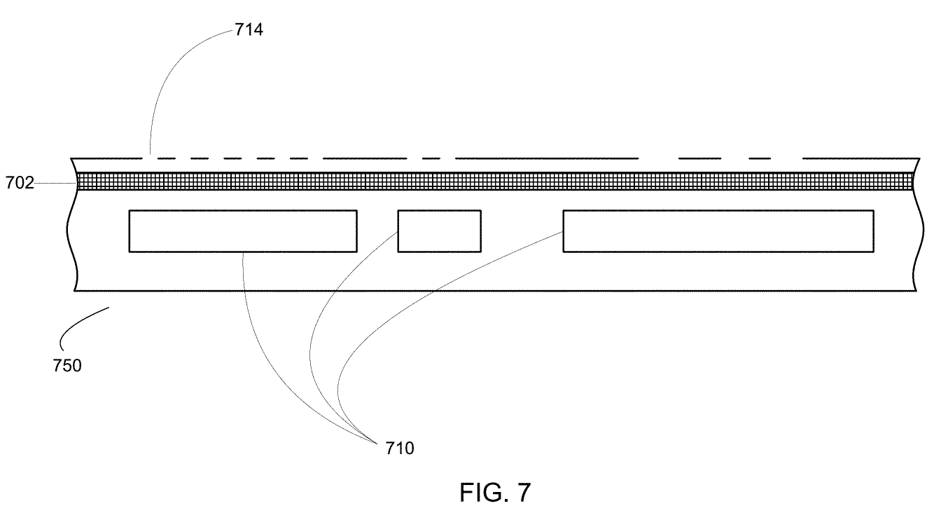

Referring now to FIG. 7, a side view of electronic device 750 wherein protective membrane 702 is integrated into the electronic device itself is shown. Protective membrane 702 absorbs heat from electronic components and circuitry 710 and which then flows out through protective membrane 702 via perforations or vent holes 714.

Perforations or vent holes 714 may be positioned in the electronic device in variety of configurations, sizes, and shapes so as to enhance heat dissipation away from the electronic components and circuitry 710.

The current embodiment displays protective membrane 702 as a single rectangular patch, but the protective membrane may exist in a multitude of configurations including, for example (but not limited to), multiple rectangular patches, circular patches, irregular shaped patches, custom fit patches for a particular electronic device, etc.

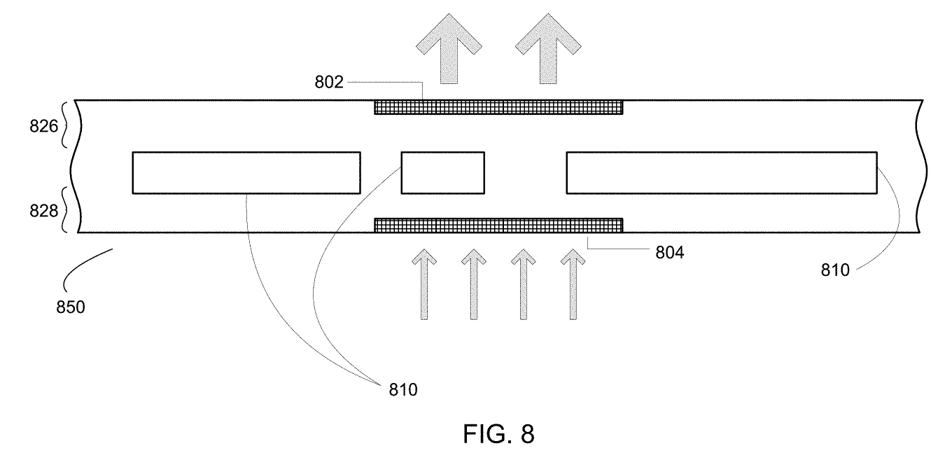

Referring now to FIG. 8, a side view of electronic device 850 wherein protective membranes 802 and 804 are integrated into the surfaces of the electronic device itself. In this embodiment, protective membranes 802 and 804 are shaped (e.g. cut, molded, woven, etc.) into rectangular strips and placed on top surface 826 and bottom surface 828 of the protective enclosure, such that they correspond to the top and bottom surfaces of the electronic device 850.

The current embodiment of the present invention displays protective membranes 802 and 804 as rectangular strips, but the protective membrane may exist in alternative configurations including multiple rectangular patches, circular patches, irregular shaped patches, custom fit patches for a particular electronic device, etc.

In one embodiment, protective membranes 802 and 804 include a flexible material. Protective membranes 802 and 804 further include a thickness and shape required to generate the type of protection desired for the invention. Protective membrane 802 is additionally characterized by hydrophobic and breathable microporous material that serves as a barrier to prevent damage to an electronic device.

In other embodiments, membranes 802 and 804 may be enclosed by an outer layer providing additional protection and which further contains perforations or vent holes.

FIG. 8 further illustrates the airflow through protective membranes 802 and 804. As illustrated, air flows in through protective membrane 804 at bottom surface 828 of the protective enclosure, absorbs heat from the electronic circuitry 810, and then flows out through protective membrane 802 at top surface 826. As described above with respect to FIG. 2, principles of natural convection apply to promote this heat dissipation away from electronic components and circuitry 810.

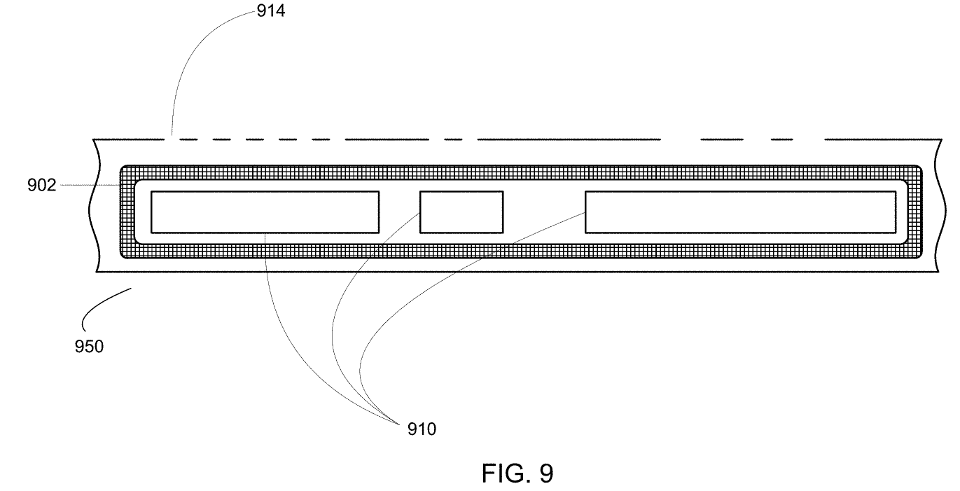

Referring now to FIG. 9, a side view of electronic device 950 wherein protective membrane 902 is integrated into the electronic device 950 is shown. The embodiment is identical to the construction embodiment described in FIG. 7 with the exception that protective membrane 902 completely surrounds electronic components and circuitry 910. This embodiment additionally illustrates perforations or vent holes 914.

Perforations or vent holes 914 may be positioned in the electronic device in variety of configurations, sizes, and shapes so as to promote heat dissipation away from the electronic components and circuitry 910.

Electronic circuitry 910 permits of number of user functions including receiving cellular signals from an internet service provider and communicate with the mobile device using a WiFi signal, running various applications and programs (e.g. music, videos, games), sending and receiving GPS information, establishing Bluetooth connections, establishing USB connections, etc.

In this embodiment, protective membranes 902 completely surrounds the portions of electronic device that generate the most heat. Specifically, protective membrane 902 surrounds electronic circuitry 910. Accordingly, the protective membrane not only dissipates heat from a primary heat source, but also prevents heat from spreading to other electronic components and further increasing the temperature of the electronic device.

Thus, various non-limiting embodiments of the present invention have been described.

In one embodiment, an apparatus is disclosed that includes circuitry as well as membrane that is configured to pass air, to remove heat from the circuitry, and to prevent the circuitry from being exposed to moisture. The membrane is additionally characterized by a porous structure. In some embodiments, the membrane includes a flexible material.

Further embodiments include an apparatus that includes electronic components and circuitry that are configured to wirelessly connect to an internet as well as an apparatus configured to wirelessly provide internet service to a mobile device.

In some embodiments, the membrane feature entirely surrounds the circuitry of an electronic device. For example, in FIG. 9, a side view of the present invention displays the membrane as completely enclosing the electronic device's circuitry and electronic components.

Other embodiments include an a multi-layer protective enclosure wherein the membrane is positioned between a rigid enclosure and the electronic device's circuitry. For example, FIG. 1 shows the front-side view of the membrane layer in between the circuitry (shown) and the rigid enclosure (not shown).

Additional embodiments include an apparatus wherein the membrane covers a first and second opening in a corresponding first and second side of the rigid enclosure. In this embodiment, the circuitry is between the first opening and the second opening. For example, FIG. 2 shows two membrane components that have been shaped (e.g. cut, molded, woven, etc.) into rectangular strips and placed at top opening and bottom opening of the apparatus. In between these top and bottom openings is the electronic device's circuitry.

For certain embodiments, the membrane serves to prevent excessive heat from damaging an electronic device. These embodiments are configured to facilitate movement of gasses heated by the electronics away from the electronics. The membrane is characterized by air permeability. In one embodiment the membrane includes an air permeability that allows one cubic foot of air or less to pass through one cubic foot of fabric in one minute.

In additional embodiments, the membrane protects electronic devices threatened by water damage. As such, the membrane is further characterized by hydrophobic properties.

While the embodiments have been described and/or illustrated by means of particular examples, and while these embodiments and/or examples have been described in considerable detail, it is not the intention of the Applicants to restrict or in any way limit the scope of the embodiments to such detail. Additional adaptations and/or modifications of the embodiments may readily appear to persons having ordinary skill in the art to which the embodiments pertain, and, in its broader aspects, the embodiments may encompass these adaptations and/or modifications. Accordingly, departures may be made from the foregoing embodiments and/or examples without departing from the scope of the concepts described herein. The implementations described above and other implementations are within the scope of the following claims.

What is claimed is:

1. An apparatus comprising:
circuitry; and
a membrane configured to pass air and remove heat from the circuitry, wherein
the membrane is further configured to prevent the circuitry from being exposed to moisture, and
the membrane includes pores.

2. The apparatus of claim 1, wherein the membrane entirely surrounds the circuitry.

3. The apparatus of claim 1, wherein the membrane includes an air permeability that allows one cubic foot of air or less to pass through one cubic foot of fabric in one minute.

4. The apparatus of claim 1, wherein the membrane is flexible.

5. The apparatus of claim 1, wherein the membrane is between a rigid enclosure and the circuitry.

6. The apparatus of claim 5, wherein the membrane covers a first opening in a first side of the rigid enclosure.

7. The apparatus of claim 6, wherein the membrane covers a second opening in a second side of the rigid enclosure, and the circuitry is between the first opening and the second opening.

8. An apparatus comprising:
electronics configured to wirelessly connect to an internet service provider; and
an enclosure surrounding the electronics; wherein
the enclosure includes a first portion and a second portion,
the first portion is more rigid than the second portion,
the second portion keeps moisture away from the electronics,
the second portion allows passage of gasses.

9. The apparatus of claim 8, wherein the second portion is configured to facilitate movement of gasses heated by the electronics away from the electronics.

10. The apparatus of claim 8, wherein the second portion includes a first section above the electronics and a second section below the electronics.

11. The apparatus of claim 8, wherein the second portion allows passage of water vapor.

12. The apparatus of claim 8, wherein the second portion entirely surrounds the electronics.

13. The apparatus of claim 12, wherein the first portion entirely surrounds the second portion.

14. The apparatus of claim 8, wherein the second portion seals openings in the first portion.

15. An apparatus comprising:
an interior environment;
circuitry configured to wirelessly provide internet service to a mobile device, wherein the circuitry is within the interior environment; and
a layer forming a boundary between the interior environment and an exterior environment, wherein
the layer is hydrophobic, and
the layer is permeable by air.

16. The apparatus of claim 15, wherein the circuitry is further configured to receive cellular signals from an internet service provider and communicate with the mobile device using a WiFi signal.

17. The apparatus of claim 15, wherein the layer is permeable by water vapor.

18. The apparatus of claim 15, wherein the layer defines the interior environment.

19. The apparatus of claim 15, wherein the layer forms a number of boundaries between the interior environment and the exterior environment.

20. The apparatus of claim 15, wherein the layer is configured to promote the movement of air heated by the circuitry through the layer.
